(19) United States
(12) Patent Application Publication
(10) Pub. No.: US 2022/0350059 A1
(43) Pub. Date: Nov. 3, 2022

(54) BRAGG MIRROR AND METHOD FOR PRODUCING A BRAGG MIRROR

(71) Applicant: COMMISSARIAT A L'ENERGIE ATOMIQUE ET AUX ENERGIES ALTERNATIVES, Paris (FR)

(72) Inventors: Corrado SCIANCALEPORE, Grenoble (FR); Houssein EL DIRANI, Grenoble (FR)

(73) Assignee: COMMISSARIAT A L'ENERGIE ATOMIQUE ET AUX ENERGIES ALTERNATIVES, Paris (FR)

(21) Appl. No.: 17/763,554

(22) PCT Filed: Sep. 24, 2020
(86) PCT No.: PCT/EP2020/076798

§ 371 Date: Mar. 24, 2022

(30) Foreign Application Priority Data
Sep. 27, 2019 (FR) FR1910714

(51) Int. Cl. G02B 5/18

(52) U.S. Cl. CPC G02B 5/1861; G02B 5/1847

(57) ABSTRACT

The invention relates to a Bragg mirror comprising a portion (110) of ribbon (100) having a refractive index n1, corrugations (112) having a refractive index n3 and a separation layer (111) separating the ribbon (100) from the corrugations (112) and having a refractive index n2, such that n2<n3 and n2<n1. The invention also relates to a method for producing such a mirror.

### TECHNICAL FIELD

The present invention relates to the field of optoelectronics. It finds for particularly advantageous application the production of Bragg mirrors for semiconductor laser sources, for example for LiDAR (acronym for the expression “laser detection and ranging”) remote sensing lasers or for medium-distance datacom lasers of the 400G Ethernet type.

### PRIOR ART

A Bragg mirror allows to reflect light radiation at normal incidence to said mirror, while limiting optical losses. It can thus have a reflectivity R greater than 99% for light radiation of given wavelength A.

Bragg mirrors are therefore particularly advantageous for the manufacture of optical cavities for laser applications, and in particular for semiconductor laser sources.

A known semiconductor laser source architecture is shown in FIGS. 1A, 1B. Such an architecture typically comprises a ribbon guide 100 extending longitudinally between two transverse Bragg mirrors 11, 12, and a Fabry-Perot type optical cavity comprising an amplifying medium 20. The amplifying medium 20 is here a vignette made of material III-V, for example made of indium phosphide InP, transferred to the silicon ribbon 100. In practice, the Bragg mirrors are produced by corrugation of the ribbon guide 100. Therefore, they each have a corrugation factor κ and a length L_{g} which determine their reflectivity properties.

The corrugation factor κ can be expressed as:

$$κ = \frac{π \cdot {n}_{eff , g}}{λ} \frac{\int {\int }_{Ω} {n}_{l o w}^{2} {n}_{high}^{2} {E}^{2} d x d y}{\int \int {E}^{2} d x d y}$$

Where Ω is the section of the optical mode propagating in the ribbon, n_{low} and n_{high} are respectively the effective refractive indices of the optical mode in correspondence with respectively the low steps and the high steps of the ribbon as illustrated in FIG. 3B, n_{eff,g}=(n_{low}−n_{high})dΛ+nᵤₚ is a global effective index of the grating formed by the corrugations (weighted average of the indices related to the low steps and high steps) and E is the electric field of the light radiation outside the region disturbed by the corrugations.

An operating principle of this laser source is as follows: the amplifying medium is electrically pumped so as to emit light radiation having an emission spectrum centred around a wavelength A This light radiation propagates in a guided manner within the optical cavity while being reflected several times by the Bragg mirrors, according to a resonant mode of propagation called cavity mode or longitudinal mode. After each reflection, the light radiation is reinjected into the amplifying medium in order to stimulate the emission. One of the Bragg mirrors, called confinement mirror, has a reflectivity R≥99% and allows to limit the optical losses of the cavity. The other Bragg mirror, called output or extraction mirror, is partially reflective (R≤50%) and allows a coherent laser beam to be transmitted.

This laser beam generally has an emission spectrum comprising a discrete set of very fine lines around the wavelength λ, at wavelengths defined by the optical cavity and the amplifying medium. This laser emission spectrum is illustrated in FIG. 2. The different lines of this emission spectrum correspond to the longitudinal modes of the laser beam. The width of the lines depends in particular on the imperfections of the optical cavity and on the quantum noise generated within the amplifying medium.

The wavelength spacing between the longitudinal modes corresponds to the free spectral range FSR_{λ} of the optical cavity, and depends in particular on the length L of the optical cavity:

$$F S {R}_{λ} = \frac{{λ}^{2}}{2 {n}_{eff} L}$$

With n_{eff} the average effective index of the optical cavity. Thus, by increasing the cavity length, the FSR_{λ} decreases and the spectral band of the laser beam potentially contains more longitudinal modes.

The laser beam can be characterised by its spectral purity, which reflects the number of longitudinal modes in its emission spectrum. The spectral purity of the laser beam increases as the number of longitudinal modes in the emission spectrum decreases. The spectral purity can be expressed as the ratio of the intensities of the two most intense lines. In telecommunications, a laser beam is considered as a single-mode laser beam of wavelength A if this ratio of intensities, also known by the acronym SMSR (for Side Mode Suppression Ratio), is greater than about 30 dB.

One solution to improve the spectral purity of the laser beam is to reduce the cavity length. This type of solution is not adapted for laser sources requiring high optical power since by reducing the cavity length, the optical power of the laser beam decreases.

Another solution to improve the spectral purity of the laser beam consists in dimensioning the output Bragg mirror so as to spectrally filter the laser beam.

The Bragg mirrors of the optical cavity each have a reflectivity peak centred on the wavelength λ.

This reflectivity peak has a certain spectral width δω_{DBR} defining the spectral stop band or “stopband” of the Bragg mirror.

This stopband width δω_{DBR} (in nm) depends in particular on the corrugation factor κ of the Bragg grating, also called grating strength, and on the length of the Bragg grating L_{g}:

$$δ {ω}_{D B R} = \frac{π}{{v}_{g} \sqrt{{\vert κ \vert}^{2} + {( \frac{π}{{L}_{g}} )}^{2}}}$$

Where v_{g} is the group speed of light radiation.

A sufficiently low stopband width δω_{DBR} of the output mirror allows to filter the emission spectrum of the laser beam and to reduce the width of this emission spectrum. The spectral purity of the laser beam is thus all the better as the stopband of the output mirror is narrow.

FIG. 3A illustrates the reflectivity R and the stopband of the confinement mirror (L₉=500 μm, R≈100%, δω_{DBR2}≈2 nm) and of the output mirror (L_{g}=100 μm, R≈46%, δω_{DBR}≈4 nm) of an optical cavity of FSR_{λ}=0.32 nm, for a light radiation of wavelength λ=1547 nm. The vertical lines illustrate the different longitudinal modes of the beam, separated by the FSR_{λ}.

In this example, the optical cavity has a length L of about 1 mm, and the confinement and output mirrors have corrugations of height t=10 nm. FIG. 3B illustrates in section a Bragg mirror of length L_{g} having such corrugations of height t, of length d over a period Λ.

This type of solution allows to obtain single-mode infrared laser sources (λ≈1550 nm) for data transmission (datacoms) or telecommunication (telecoms) applications requiring an optical power comprised between 5 mW and 20 mW.

On the other hand, for applications of the LiDAR (laser detection and ranging) type or medium-distance datacom applications of the 400G Ethernet type, this type of solution does not allow to obtain both sufficient power, typically greater than 100 mW, and a single-mode laser beam.

To achieve the optical powers required for these applications, the length of the amplifying medium and therefore the length L of the optical cavity must be increased. In particular, the length of the optical cavity can be at least three times greater than that of the previous example. This increase in cavity length proportionally induces a decrease in the free spectral range FSR_{λ}.

The features of the output mirror of the previous example no longer allow to obtain a single-mode beam for such an optical cavity. In particular, the stopband width of the output mirror (δω_{DBR}≈4 nm) is too large compared to the free spectral range (FSR_{λ}≈0.11 nm) of such an optical cavity.

There is therefore a need consisting in proposing an output Bragg mirror for a semiconductor laser having a reduced stopband width.

An object of the present invention is to provide such an output Bragg mirror.

In particular, an object of the present invention is to provide an output Bragg mirror for a semiconductor laser improving the spectral purity of the laser beam, in particular for a semiconductor laser having an optical power greater than or equal to 100 mW.

Another object of the present invention is to provide a method for producing such an output Bragg mirror.

The other objects, features and advantages of the present invention will become apparent from a review of the following description and the accompanying drawings. It is understood that other advantages may be incorporated. In particular, some features and some advantages of the Bragg mirror may apply mutatis mutandis to the optical system and/or to the method, and vice versa.

### SUMMARY

To achieve this purpose, a first aspect relates to a Bragg mirror comprising a first ribbon part based on a first material having a first refractive index n1, said ribbon extending mainly in a first direction x and being intended to guide a propagation of a light radiation of wavelength λ in said first direction x, the Bragg mirror further comprising corrugations at least at one face of said first ribbon part, said corrugations extending mainly in a second direction y normal to the first direction x and having a height h3 in a third direction z normal to the first and second directions x, y.

Advantageously, the corrugations are separated from said at least one face of the first ribbon part by a separation layer based on a second material having a thickness e2 taken in the third direction z and having a second refractive index n2.

Advantageously, the corrugations are based on a third material having a third refractive index n3, such that n2<n3 and n2<n1.

Thus, the corrugations are opposite the face of the ribbon and separated from said face of the ribbon by the separation layer.

The ribbon guides the propagation of the light radiation along x, longitudinally. The optical mode(s) of the light radiation are therefore confined in the ribbon. The ribbon thus has dimensions along the transverse directions y, z that are less and preferably much less than its dimension along x, and for example at least 100 times smaller for at least one of the directions y, z. The confinement is typically achieved by sheathing the ribbon with a low refractive index material. The confinement is thus achieved by contrast of indices, between the ribbon itself and the sheath surrounding the ribbon. The optical confinement can also be partly due to the geometry of the ribbon, typically to the shape of its cross section.

Such a ribbon forming an optical guide is therefore distinct from a substrate, which generally extends both in x and in y. A substrate does not allow to guide a propagation of a light radiation in one direction or in a single direction. A substrate is typically intended to carry a plurality of devices. In particular, a substrate can carry the ribbon guide associated with the Bragg mirror according to the invention.

The ribbon and the mirror comprising part of this ribbon are thus intended for the field of guided optics. The ribbon is preferably single-mode, that is to say that it guides a single mode of propagation of the light radiation, typically the fundamental mode. The ribbon part integrated into the mirror typically has the same features as the ribbon itself. This part of the ribbon allows in particular to confine the light radiation. Fractions of the light radiation confined in the ribbon part of the mirror are thus reflected along x, by each of the corrugations of the mirror. The fractions reflected in phase thus reform a light radiation reflected along x. The mirror therefore performs a primary reflection function, but also comprises a light propagation function.

The corrugations disturb the propagation of light radiation. The corrugation factor κ thus partly determines the stopband width δω_{DBR}. The greater the corrugation factor, the greater the stopband width of the mirror. Conversely, when the corrugation factor decreases, the stopband width of the mirror decreases.

One solution allowing to reduce the corrugation factor consists in reducing the height of the corrugations. In the context of the development of the present invention, it has turned out in practice that the etching technologies required to obtain, in a reproducible and controlled manner, corrugations having a height of the order of a few nanometres are very difficult to implement.

On the contrary, in the present case, the reduction of the corrugation factor is obtained by overcoming a reduction in the height of the corrugations.

Thus, the use of a separation layer allows to physically distance the corrugations from the ribbon wherein the light radiation propagates. The intensity of the disturbances decreases with increasing distance, in the third direction z, between the corrugations and the ribbon. The corrugation factor κ and the stopband width δω_{DBR} of the Bragg mirror are thus reduced by this physical distance or separation effect.

The use of a second material for this separation layer, typically a dielectric material, having a low refractive index relative to those of the ribbon and the corrugations further allows to optically separate the corrugations from the ribbon wherein the light radiation propagates.

The separation layer of refractive index n2 therefore has a synergistic effect by physically separating the corrugations from the ribbon, and by optically modulating the light radiation with a low index. This allows to further reduce the stopband width of the Bragg mirror.

The corrugations are thus “floating” with respect to the ribbon. From an electromagnetic point of view, the corrugations form islands disturbing the electromagnetic field of the light radiation propagating in the ribbon. The electromagnetic disturbances of the light radiation are attenuated by a dielectric barrier. They further decrease naturally with increasing distance between the islands and the ribbon. These floating corrugations have a reduced corrugation factor.

Another aspect relates to a method for manufacturing a Bragg mirror comprising the following steps:
Providing a ribbon based on a first material having a first refractive index n1, said ribbon extending mainly in a first direction x and having a face extending in a main extension plane xy formed by the first direction x and a second direction y normal to the first direction x,
Depositing at least on a first part of said face of the ribbon a separation layer based on a second material having a second refractive index n2 such that n2<n1, said separation layer having a thickness e2 taken in a third direction z normal to the first and second directions x, y,
Depositing, on the separation layer, a disturbance layer based on a third material having a third refractive index n3, such that n2<n3, said disturbance layer having a thickness e3 taken in the third direction z,
Etching the disturbance layer so as to form corrugations extending mainly in the second direction y, and having a height h3≤e3 in the third direction z.

The height h3 of the corrugations is preferably greater than 10 nm, and preferably greater than 20 nm. The etching of such a height h3 is more easily achievable than an etching of less than a few nanometres, for example less than 5 nm. The step of etching the corrugations according to the method of the invention is therefore simplified compared to a solution aiming at reducing the height of the corrugations. Advantageously, the separation layer can serve as a stop layer for the etching of the disturbance layer and h3=e3. Thus, the height h3 of the corrugations is perfectly reproducible and well controlled. The face of the ribbon is also protected from possible over-etching during the etching of the corrugations. This allows to produce a Bragg mirror with a high quality factor.

### BRIEF DESCRIPTION OF FIGURES

The aims, objects, as well as the features and advantages of the invention will emerge better from the detailed description of an embodiment of the latter which is illustrated by the following accompanying drawings wherein:

FIGS. 1A and 1B respectively illustrate in top and sectional view a known semiconductor laser source architecture.

FIG. 2 shows a typical emission spectrum of a laser.

FIG. 3A illustrates the reflectivity and the stopband of the confinement and output mirrors of a laser according to the prior art.

FIG. 3B illustrates in section a Bragg mirror having corrugations according to the prior art.

FIG. 4A shows a sectional view in a plane yz of a Bragg mirror according to one embodiment of the present invention.

FIG. 4B shows a sectional view in a plane xz of a Bragg mirror according to one embodiment of the present invention.

FIG. 5A shows a top view of a Bragg mirror according to one embodiment of the present invention.

FIG. 5B shows a top view of a Bragg mirror according to another embodiment of the present invention.

FIG. 6A shows the reflectivity and the stopband of a Bragg mirror according to the prior art.

FIG. 6B shows the reflectivity and the stopband of a Bragg mirror according to one embodiment of the present invention.

The drawings are given by way of examples and do not limit the invention. They constitute schematic principle representations intended to facilitate the understanding of the invention and are not necessarily scaled to practical applications. In particular, the relative dimensions of the different layers and corrugations of the Bragg mirror are not representative of reality.

### DETAILED DESCRIPTION

Before starting a detailed review of embodiments of the invention, it is recalled that the invention according to its first aspect comprises in particular the optional features below which can be used in combination or alternatively:

According to one example, the corrugations are separated from each other so that the separation layer is exposed between said corrugations.

According to one example, the corrugations are encapsulated in an encapsulation layer based on the second material.

According to one example, the height h3 of the corrugations is greater than or equal to 5 nm and/or less than or equal to 30 nm.

According to one example, the thickness e2 of the separation layer is greater than or equal to 10 nm and/or less than or equal to 50 nm.

According to one example, the corrugations have an adiabatic pattern projecting in a main extension plane xy formed by the first and second directions x, y.

According to one example, the height h3 and the thickness e2 are configured so that the mirror has a spectral bandwidth δω_{DBR} less than or equal to 0.5 nm.

According to one example, the first refractive index n1 is greater than or equal to 3, the second refractive index n2 is less than or equal to 2, and the third refractive index n3 is greater than or equal to 1.5.

According to one example, the third and second indices of refraction are such that n3−n2≤0.5.

According to one example, the first material is silicon, the second material is a silicon oxide, the third material is taken from a silicon nitride, an aluminium nitride, an aluminium oxide, a tantalum oxide.

According to one example, the ribbon forms a single-mode guide.

According to one example, the first ribbon part is configured to cooperate with a ribbon forming a single-mode guide.

According to one example, the mirror has an input and an output extending along a plane transverse to the first direction x of propagation of the light radiation. The mirror is thus capable of admitting and returning the light radiation in a third part of the ribbon, coupled to the first part.

According to one example, the corrugations are comprised in a layer, called the disturbance layer, parallel to the first direction x of propagation of the light radiation.

According to one example, the first part of the ribbon rests on an underlying layer having a refractive index less than the first refractive index n1, so that the light radiation is confined in the third direction (z).

According to one example, the first part of the ribbon has lateral flanks parallel to a plane xz, and the lateral flanks are bordered by at least one lateral layer having a refractive index less than the first refractive index n1, so that the light radiation is confined in the second direction (y).

According to one example, the mirror forms with the ribbon an optical system. This optical system comprising the mirror and the ribbon can advantageously be implemented in the context of the production of guided optical devices, for example lasers.

According to one example, the first part of the ribbon corresponds to a central part of greater thickness of a ridge guide.

The invention according to another aspect comprises in particular the following optional features which can be used in combination or alternatively:

According to one example, the method further comprises encapsulating the corrugations by an encapsulation layer based on the second material.

According to one example, the etching is stopped at an interface between the separation layer and the disturbance layer, so that the height h3 of the corrugations is equal to the thickness e3 of the disturbance layer.

According to one example, the etching has a selectivity S_{p:s} between the disturbance and separation layers greater than or equal to 2:1, preferably greater than or equal to 50:1.

According to one example, the height h3 of the corrugations is greater than or equal to 5 nm and/or less than or equal to 30 nm and the thickness e2 of the separation layer is greater than or equal to 20 nm and/or less than or equal to 50 nm.

Except incompatibility, it is understood that the mirror, the manufacturing method, and the optical system may comprise, mutatis mutandis, all the optional features above.

In the context of the present invention, the terms “Bragg mirror”, “Bragg grating” or “Distributed Bragg Reflector” or else “DBR” are used as synonyms. The Bragg mirror is here configured to be used as a reflector in a waveguide. It comprises an alternation of materials with different refractive indices. This alternation induces a periodic variation of the effective refractive index in the waveguide. Such an alternation is reproduced at least twice in the context of a Bragg mirror according to the present invention.

The waveguide cooperating with the Bragg mirror is preferably a ribbon type waveguide used in particular for ribbon laser applications. A ribbon laser can be of the DBR type (for Distributed Bragg Reflector) or of the DFB type (for Distributed FeedBack). A DBR laser typically comprises two Bragg mirrors. A DFB laser typically comprises a single Bragg mirror.

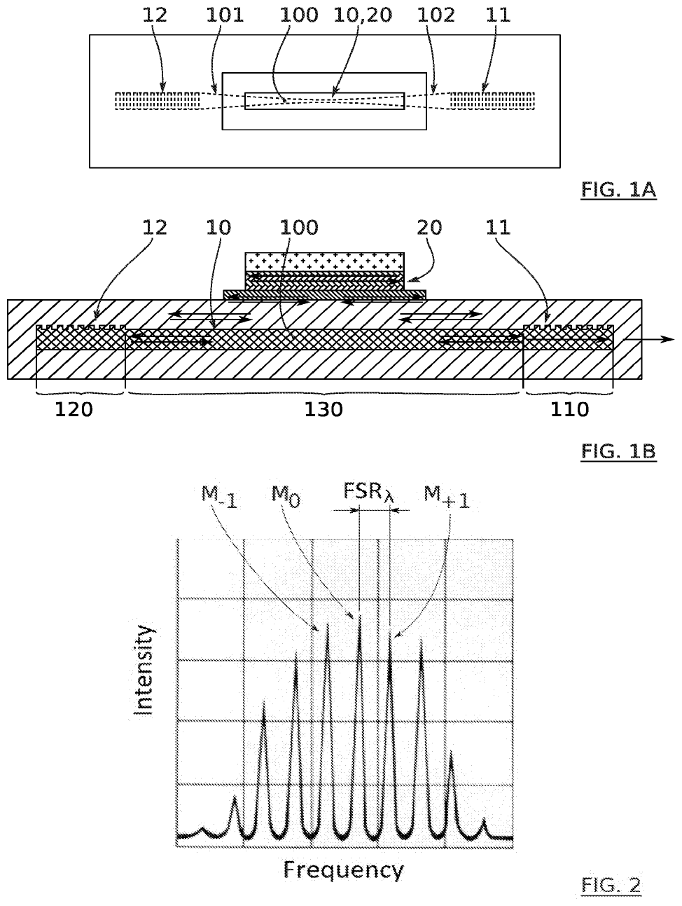

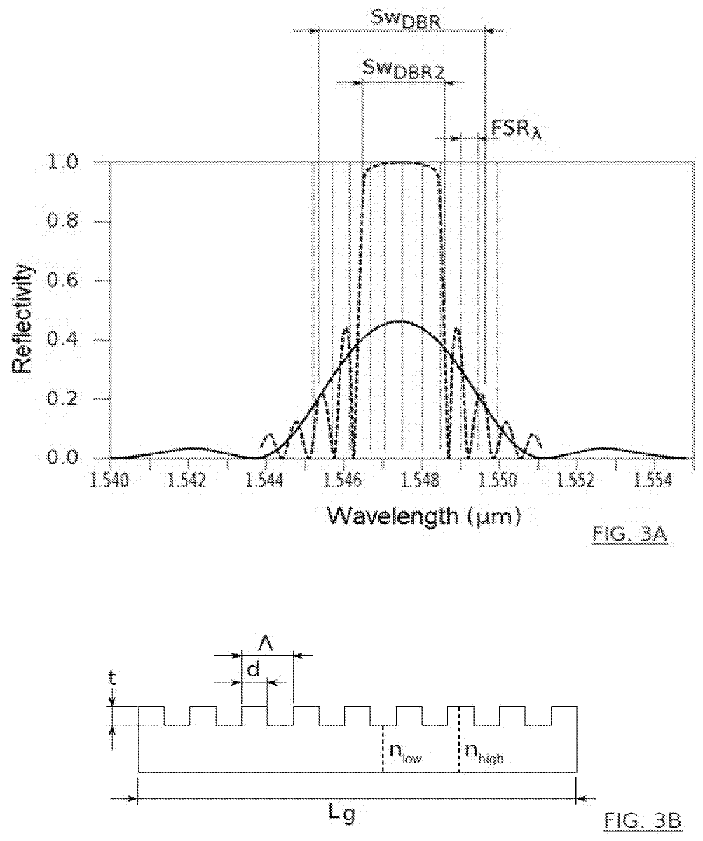

The ribbon extends continuously along a main direction x. It guides the propagation of light radiation along x. As illustrated in FIG. 1A, the section of the ribbon in a plane yz is not necessarily constant along the ribbon 100. In particular, one or more tapers 101, 102 can locally modulate the propagation of the light radiation. This allows for example an adiabatic passage between the propagation of the light radiation in the part 10 (ribbon) of the cavity and the propagation of the light radiation in the part 20 (amplifying medium) of the cavity. The ribbon section can also have a variable shape. According to the example illustrated in FIG. 1A, it may be rectangular at the Bragg mirrors 11, 12, and may have a ridge profile at the optical cavity 10. In the context of the present invention, the ribbon may designate a ribbon or strip guide, or may designate only a part of a ridge or rib guide, typically the thickest central part of a ridge guide. Thus, a ridge or rib guide comprises a ribbon within the meaning of the present invention.

The ribbon typically comprises several parts contributing respectively to the formation of the Bragg mirror(s) and the optical cavity of a DBR or DFB type ribbon laser. As illustrated in FIG. 1B, a first part 110 of the ribbon 100 corresponds to a first Bragg mirror 11, a second part 120 of the ribbon 100 corresponds to a second Bragg mirror 12, and a third part 130 of the ribbon 100 corresponds to the optical cavity. The part of the ribbon comprised in the Bragg mirror therefore cooperates with the rest of the ribbon. In this sense, the Bragg mirror here means an assembly comprising not only a mirror strictly speaking, but also a part of a ribbon forming a medium for the propagation of light radiation.

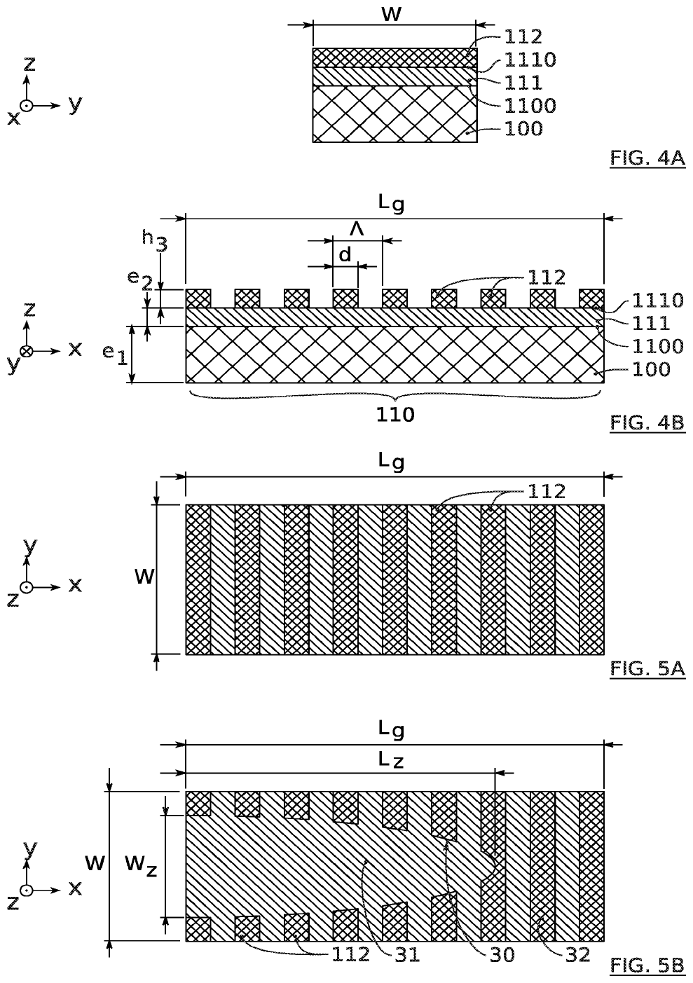

The Bragg mirror(s) comprise corrugations at least at one face of the ribbon. These corrugations protrude from the face of the ribbon. They extend transversely to the main longitudinal direction x. A “corrugation” therefore corresponds to a prominent transverse relief. The corrugations of a Bragg mirror according to the prior art are typically directly in contact with the face of the ribbon (FIG. 3B). The corrugations of a Bragg mirror according to the present invention are typically separated from the ribbon face by a separation layer (FIG. 4B).

It is specified that, in the context of the present invention, a third layer interposed between a first layer and a second layer does not necessarily mean that the layers are directly in contact with each other, but means that the third layer is either directly in contact with the first and second layers, or separated therefrom by at least one other layer or at least one other element, unless otherwise provided.

The layer formation steps, in particular those of separation and that of disturbance, are understood in the broad sense: they can be carried out in several sub-steps which are not necessarily strictly successive.

A substrate, a film, a layer, “based” on a material M, means a substrate, a film, a layer comprising this material M only or this material M and possibly other materials, for example alloy elements, impurities or doping elements. Where appropriate, the material M may have different stoichiometries. Thus, a layer made of a material based on silicon nitride can for example be a layer of SiN or a layer of Si3N4 (generally called stoichiometric silicon nitride).

In the present patent application, the first, second and third directions correspond respectively to the directions carried by the axes x, y, z of a preferably orthonormal reference frame. This reference frame is shown in the appended figures.

In the following, the length is taken in the first direction x, the width is taken in the second direction y, and the thickness is taken in the third direction z.

In the following, a refractive index is defined for a material, possibly for an average or model material, and for a wavelength of light radiation in this material. The refractive index is equal to the ratio of the celerity c (speed of light in vacuum) to the speed of propagation of light in the material considered. The light is assumed to propagate along the longitudinal direction x.

n1 is a first refractive index for a propagation of a luminous flux of wavelength λ in the first material.

n2 is a second refractive index for a propagation of a luminous flux of wavelength λ in the second material.

n3 is a third refractive index for a propagation of a luminous flux of wavelength λ in the third material.

The terms “substantially”, “approximately”, “of the order of” mean “within 10%” or, in the case of an angular orientation, “within 10°”. Thus, a direction substantially normal to a plane means a direction having an angle of 90±100 relative to the plane.

To determine the geometry of a Bragg mirror, Scanning Electron Microscopy (SEM) or Transmission Electron Microscopy (TEM) analyses can be carried out. These techniques are well adapted for determining the dimensions of nanometric structures. They can be implemented from metallurgical sections or thin sections made through the devices, according to typical construction analysis or reverse engineering methods.

The chemical compositions of the different materials can be determined from EDX or X-EDS type analyses (acronym for “energy dispersive x-ray spectroscopy”). This technique is well adapted to analyse the composition of small structures such as thin corrugations. It can be implemented on metallurgical sections within a Scanning Electron Microscope (SEM) or on thin sections within a Transmission Electron Microscope (TEM).

Reflectivity and the stopband measurements of a Bragg mirror can be performed by infrared spectroscopy, for example by Fourier Transform Infrared (FTIR) spectroscopy. The stopband width of a Bragg mirror is measured at mid-height. The reflectivity and the stopband of a Bragg mirror can also be determined through finite difference time domain calculations, called FDTD (Finite Difference Time Domain) methods.

The invention will now be described in detail through a few non-limiting embodiments.

With reference to FIGS. 4A, 4B and 5A, a first embodiment of a Bragg mirror 11 comprises a first ribbon 100 part 110 made of silicon, a separation layer 111 made of silicon oxide directly formed on a face 1100 of the part 110, and corrugations 112 made of silicon nitride directly formed on a face 1110 of the separation layer 111.

The part 110 may alternatively be made of a silicon alloy, for example silicon-germanium, or germanium. It has a refractive index n1 typically greater than 3. It has a thickness e1 for example of the order of 500 nm. It can be formed by lithography/etching from a Silicon On Insulator SOI or Germanium On Insulator GeOI type substrate. This part 110 can have a length L_{g} of the order of 50 μm to 1000 μm, and a width W of the order of 5 μm to 20 μm. The part 110 is thus typically bordered by an underlying oxide layer and by lateral oxide layers (not shown).

The face 1100 of this part 110 is advantageously not structured, unlike the known solutions resorting to periodic structuring in the form of corrugations of the face of the ribbon. The problems of complex etching of very thin corrugations (<5 nm) are thus advantageously eliminated. Part 110 is bordered by the separation layer 111 at its face 1100.

The separation layer 111 has a thickness e2 preferably comprised between 10 nm and 50 nm, for example comprised between 20 nm and 40 nm. It has a refractive index n2 less than 2. The formation of such a separation layer 111 of silicon oxide is perfectly known and easily achievable. It can be formed by thermal oxidation of the silicon exposed at the face 1100 of the part 110 of the ribbon 100. Alternatively, it can be deposited by deposition techniques, for example of the Chemical Vapour Deposition type CVD. The separation layer 111 covers the entire face 1100.

The corrugations 112 are preferably directly in contact with the separation layer 111. They have a height h3 greater than 5 nm, preferably greater than 10 nm, for example of the order of 20 nm to 25 nm, or even up to about 50 nm. Such a range of height h3 of corrugations allows finer adjustment of the mirror corrugation factor.

The corrugations 112 have a length d and a period A calculated as a function of the wavelength λ of the light radiation.

Typically, the length d is equal to:

$$d = \frac{λ}{4 \cdot neff}$$

The period Λ is equal to:

$$Λ = \frac{λ}{2 \cdot neff}$$

For radiation with a wavelength λ approximately equal to 1.5 μm, the length d is typically around 150 nm and the period Λ is typically around 250 nm. The width of the corrugations is preferably greater than or equal to W. A width of the corrugations slightly greater than the width W of the ribbon 100 allows to overcome any misalignments along z of the corrugations with respect to the ribbon. The probability that the corrugations 112 cover the entire width W of the ribbon is thus improved. The dimensioning of the corrugations in the plane xy is known per se.

The corrugations have a refractive index n3 greater than 1.5 and greater than n2. They are preferably made of silicon nitride. They can be alternatively and without limitation made of aluminium nitride, or of aluminium oxide, or of tantalum oxide.

The formation of the corrugations preferably takes place in two steps. A first step consists in depositing, for example by CVD, a layer called disturbance layer on the separation layer 111. This disturbance layer has a thickness e3. A second step consists in structuring the disturbance layer by lithography/etching so as to form the corrugations 112. The etching is preferably done by a dry process. The etching depth corresponds to the height h3 of the corrugations. The corrugations 112 are preferably distinct and separated from each other, as shown in FIG. 4B. In this case, h3=e3 and the face 1110 of the separation layer 111 is exposed between the corrugations after etching. The separation layer 111 therefore advantageously serves as an etching stop layer. The etching preferably has a selectivity S_{p:s} between the disturbance and separation layers greater than or equal to 2:1, in the case of dry etching, or even 50:1, in particular in the case of wet etching.

Alternatively, the corrugations 112 have a height h3 less than the thickness e3 of the disturbance layer. They are interconnected by a lower part of the disturbance layer in contact with the separation layer 111. The etching is in this case stopped before reaching the face 1110 of the separation layer 111.

After etching, the corrugations 112 are preferably encapsulated by a deposit of silicon oxide, for example by CVD. The encapsulation layer preferably covers the entire face of the mirror comprising the corrugations and opposite the ribbon; it also advantageously fills the spaces between the corrugations, thus covering the exposed portions of the separation layer (which mean portions not covered by corrugations).

According to this first embodiment, the corrugations are thus similar to silicon nitride bars embedded in a matrix of silicon oxide, as illustrated in FIG. 5A. The corrugations preferably have a constant width. The Bragg mirror thus formed comprises a few dozen corrugations along its length L_{g}. The number of corrugations is for example comprised between 10 and 100.

According to a second embodiment illustrated in FIG. 5B, the corrugations 112 are arranged in a pattern called adiabatic pattern. Only this arrangement of the corrugations differs from the first embodiment, all things being equal. Such an adiabatic pattern has in the plane xy a tapered profile 30, for example a pointed or parabola profile, delimiting a first zone 31 without corrugations and a second zone 32 with corrugations 112. The face 1110 of the separation layer 111 is in this case exposed over the entire zone 31 devoid of corrugations 112. The zone 31 is preferably centred on the zone 32 in the direction y.

Such an adiabatic pattern allows, in a known manner, to gradually modulate the propagation of the light radiation during reflection on the Bragg mirror. This allows to limit the optical losses by diffraction at the Bragg mirror. The parasitic losses of the optical cavity are thus limited. The zone 31 thus has a gradually decreasing width from a first side of the mirror intended to adjoin the optical cavity or the waveguide wherein the light radiation propagates, towards the second side of the mirror opposite the first side in the direction x. The zone 32 comprises parts of corrugations bordering the zone 31, and complete corrugations—that is to say extending along the entire width W—at the second side of the mirror. The number of complete corrugations in the zone 32 can be comprised between 5 and 20.

The maximum width Wz of the zone 31 is preferably less than the width W of the zone 32. The width ratio Wz/W can be comprised between 0.5 and 0.9. The length Lz of the zone 31 is less than the length Lg of the zone 32. The ratio of the lengths Lz/Lg can be comprised between 0.5 and 0.9. The area of the zone 31 may be smaller than that of the zone 32. The ratio of the areas of the zones 31, 32 may be comprised between 0.5 and 0.9.

The Bragg mirrors thus formed according to these first and second embodiments have a reduced stopband width. The Bragg mirror formed according to the second embodiment further has an improved efficiency.

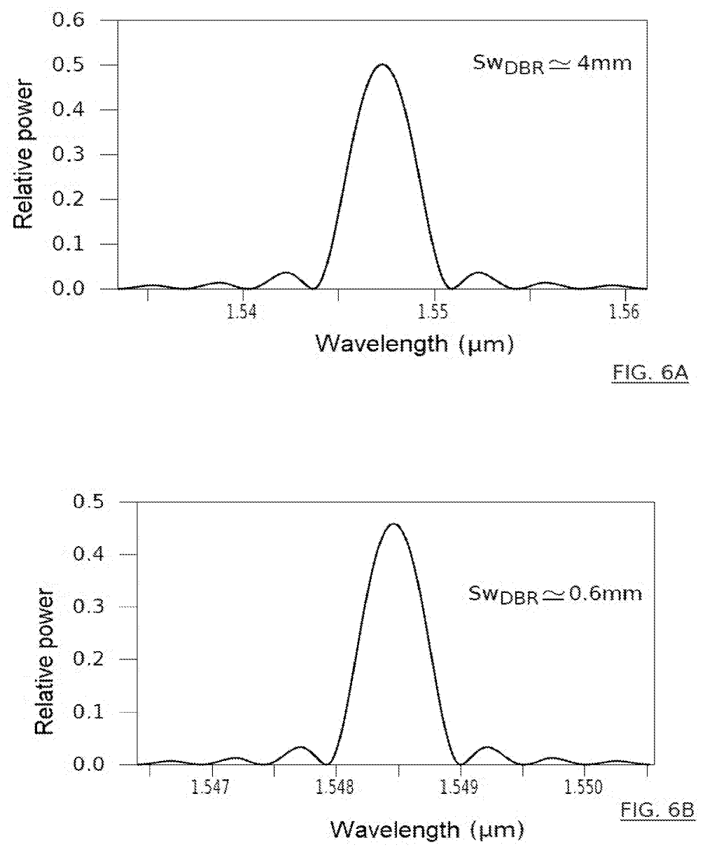

FIGS. 6A and 6B compare the stopband widths δω_{DBR} of a mirror according to the prior art (FIG. 6A) and of a mirror according to the present invention (FIG. 6B). For similar reflectivities of the order of 50%, the stopband width of the mirror according to the invention (δω_{DBR}=0.6 nm, FIG. 6B) is very significantly reduced compared to the stopband width of the mirror according to the prior art (δω_{DBR}≈4 nm, FIG. 6A). A stopband width δω_{DBR}≈0.6 nm presented in this example is not a stopband width limit value of a mirror according to the invention. This stopband width can be further reduced, for example by increasing the thickness e2 of the separation layer and/or by decreasing the height h3 of the corrugations.

Such a Bragg mirror can advantageously be implemented as an output mirror of a DBR type ribbon laser. In particular, the architecture called III-V architecture on Si illustrated in FIGS. 1A and 1B can be used by replacing the mirror 11 according to the prior art by the Bragg mirror described in the present invention. The use of this mirror with a reduced stopband width allows to lengthen the optical cavity 10 while maintaining a single-mode laser beam. By lengthening the optical cavity by a factor X with respect to a length L of a cavity of a laser taken as reference, the free spectral range FSR_{λ} reduced by the same factor X. To keep the SMSR ratio of the reference laser beam, it is then necessary to reduce the stopband width by this same factor X.

Therefore, it appears clearly that the Bragg mirror according to the invention is suitable for producing a III-V ribbon laser on Si of the DBR type having an optical cavity X times larger than that of the reference laser. By proportionally increasing the length, and therefore the volume, of the amplifying medium, the power of such a laser is also about X times greater than that of the reference laser. The Bragg mirror according to the invention therefore allows to produce a III-V laser on Si approximately X times more powerful than a reference laser comprising a Bragg mirror according to the prior art. This factor X is at least 6 in the context of the present invention.

A III-V laser on Si comprising an output mirror as described in the present invention can thus have a cavity length L of the order of 3 mm, an amplifying medium length of the order of 2 mm and an FSR_{λ} of the order of 0.11 nm. Such a laser advantageously has an optical power greater than or equal to 100 mW, while maintaining an SMSR greater than 30 dB for an emission wavelength of the order of 1.5 μm. The confinement mirror 12 of this laser preferably comprises corrugations formed directly on the part 120 of the ribbon 100. It thus has a stopband width much greater than that of the output mirror 11. This allows to benefit from an almost total reflectivity (R≥99%) over a wide band (for example δω_{DBR2}≥10 nm) for the mirror 12, and from a semi-reflectivity (R≤50%) on a very fine band (for example δω_{DBR}≤0.6 nm) for the mirror 11. Such a laser can be used advantageously for LiDAR and long-distance 400G telecom applications.

The invention is not limited to the embodiments described above and extends to all the embodiments covered by the claims.

1. A Bragg mirror comprising a first ribbon part based on a first material having a first refractive index n1, said ribbon extending mainly in a first direction x and being intended to guide a propagation of a light radiation of wavelength λ in said first direction x, the Bragg mirror further comprising corrugations at least at one face of said first ribbon part, said corrugations extending mainly in a second direction y normal to the first direction x and having a height h3 in a third direction z normal to the first and second directions, wherein the corrugations are separated from said at least one face of the first ribbon part by a separation layer based on a second material having a thickness e2 taken in the third direction z and having a second refractive index n2, and in that the corrugations are based on a third material having a third refractive index n3, such that n2<n3 and n2<n1.

2. The mirror according to claim 1 wherein the corrugations are separated from each other so that the separation layer is exposed between said corrugations.

3. The mirror according to claim 1, wherein the corrugations are encapsulated in an encapsulation layer based on the second material.

4. The mirror according to claim 1, wherein the height h3 of the corrugations is greater than or equal to 5 nm and/or less than or equal to 30 nm.

5. The mirror according to claim 1, wherein the thickness e2 of the separation layer is greater than or equal to 10 nm and/or less than or equal to 50 nm.

6. The mirror according to claim 1, wherein the corrugations have an adiabatic pattern projecting in a main extension plane xy formed by the first and second directions.

7. The mirror according to claim 1, wherein the height h3 and the thickness e2 are configured so that the mirror has a spectral bandwidth δω_{DBR} less than or equal to 0.5 nm.

8. The mirror according to claim 1, wherein the first refractive index n1 is greater than or equal to 3, the second refractive index n2 is less than or equal to 2, and the third refractive index n3 is greater than or equal to 1.5.

9. The mirror according to claim 1, wherein the third and second indices of refraction are such that n3−n2≤0.5.

10. The mirror according to claim 1, wherein the first material is silicon, the second material is a silicon oxide, the third material is taken from a silicon nitride, an aluminium nitride, an aluminium oxide, a tantalum oxide.

11. The mirror according to claim 1, wherein the first ribbon part is configured to cooperate with a ribbon forming a single-mode guide.

12. The mirror according to claim 1, wherein the first part of the ribbon rests on an underlying layer having a refractive index less than the first refractive index n1, so that the light radiation is confined in the third direction z.

13. A method for manufacturing a Bragg mirror comprising the following steps:
providing a ribbon based on a first material having a first refractive index n1, said ribbon extending mainly in a first direction x and having a face extending in a main extension plane y formed by the first direction x and a second direction y normal to the first direction x,
depositing at least on a first part of said face of the ribbon a separation layer based on a second material having a second refractive index n2 such that n2<n1, said separation layer having a thickness e2 taken in a third direction z normal to the first and second directions,
depositing, on the separation layer, a disturbance layer based on a third material having a third refractive index n3, such that n2<n3, said disturbance layer having a thickness e3 taken in the third direction z,
etching the disturbance layer so as to form corrugations extending mainly in the second direction y, and having a height h3≤e3 in the third direction z.

14. The method according to claim 13 further comprising encapsulating the corrugations by an encapsulation layer based on the second material.

15. The method according to claim 13, wherein the etching is stopped at an interface between the separation layer and the disturbance layer, so that the height h3 of the corrugations is equal to the thickness e3 of the disturbance layer.

16. The method according to claim 13, wherein the height h3 of the corrugations is greater than or equal to 5 nm and/or less than or equal to 30 nm and the thickness e2 of the separation layer is greater than or equal to 20 nm and/or less than or equal to 50 nm.
